(19) United States
(12) Patent Application Publication
(10) Pub. No.: US 2001/0014397 A1
(43) Pub. Date: Aug. 16, 2001

(54) Method for producing a wafer support, used, in particular, in a high-temperature CVD reactor or in a high-temperature CVD process which involves the use of aggressive gases

(76) Inventors: Dietmar Schmitz, Aachen (DE); Johannes Kaeppeler, Wurselen (DE); Gert Strauch, Aachen (DE); Holger Jurgensen, Aachen (DE); Michael Heuken, Aachen (DE)

Correspondence Address: ST. ONGE STEWARD JOHNSTON & REENS, LLC, 986 BEDFORD STREET, STAMFORD, CT, 06905-5619, US

(21) Appl. No.: 09/752,395

(22) Filed: Dec. 28, 2000

Related U.S. Application Data
(63) Continuation of application No. PCT/DE00/01312, filed on Apr. 26, 2000.

(30) Foreign Application Priority Data
Apr. 30, 1999 (DE) 199 19 902.7

(51) Int. Cl. B32B 9/00; C23C 16/32; C23C 16/34; B05C 13/02

(52) U.S. Cl. 428/408; 427/248.1; 427/299; 427/255.4; 427/249.1; 118/500

(57) ABSTRACT

What is described here is a method of producing a wafer support having a protective layer, which, after the specifically mechanically prefabricated wafer support has been cleaned, is characterized by heating the cleaned wafer support to temperatures, by introducing coating components for conversion of the wafer support surface into the protective layer or for deposition of components supplied to a protective layer.

The invention excels itself by the provisions that the inventive wafer support with the specific coating is suitable for a system for and a method of high-temperature CVD processing of wafers, operating on aggressive gases, in such a way that a chemical interaction with the wafer support will not occur, apart from the reproducible deposition of the desired succession of layers with a very good homogeneity of the material characteristics.

This is a continuation of pending International Application PCT/DE00/01312 filed on Apr. 26, 2000, which designates the United States.

The present invention relates to a method of producing specific wafer supports which are expediently used particularly in a system for or in appropriate methods of high-temperature wafer coating by means of aggressive gases.

### PRIOR ART

At present the possibility is available to deposit materials, particularly connecting semiconductor materials, on a substrate by means of CVD methods such as the MOVPE process. In that process the components of the stratum to be deposited are made available in the form of a gas in a reactor. In the respective steps of process these gases interact not only with the substrate to be coated but also with their environment inside the reactor. With the wafer support normally having a temperature higher than the temperature of the support or the substrate, respectively, there is likewise an intensive interaction with the wafer support, which results in an influence on the process. These influences on the processes are difficult to minimise in the CVD or MOVPE methods which operate on conventional wafer supports.

In particular, a non-reproducible influence is produced on the deposition, with the desirable characteristics of the stratum being subjected to negative influences. The efficiency of the layers so produced may be impaired and/or the service life of the circuit to be produced may be shortened, for instance. In view of the desired minimum demands on the materials to be produced, such as connecting semiconductors, deposited materials with impaired characteristics must be classified as rejects, which results in higher manufacturing costs.

### BRIEF DESCRIPTION OF THE INVENTION

The present invention is now based on the problem of providing a method and a system as well as the method of producing the wafer support of this system, wherein the high-temperature coating of wafers by means of aggressive gases such as ammoniac or gases containing halides such as HCl may be performed. It is the intention to optimise known CVD methods and specifically MOVPE processes in such a way that they are better to control and to reproduce and that the products present the desired characteristics with respect to their quality and the demands made on them.

This means that it is the objective of the present invention to achieve a reproducible deposition of the desired successions of layers on wafers in CVD methods such as the MOVPE process, it being the aim that the desired material characteristics are present with a very sound degree of homogeneity.

The problem is solved by a specific wafer support which is produced by an inventive method according to claim 1 and which is suitable for application in CVD or MOVPE systems and methods in particular.

In an approach to overcome the disadvantages of the conventional wafer supports it is the objective that the inventive wafer support will not chemically interact with the process gases in the CVD method in particular.

This means that the inventive wafer support should be physically and chemically configured for resisting loads, particularly loads induced by high-temperature CVD processes or MOVPE processes operating on aggressive gases.

The inventive method provides the inventive wafer support.

The inventive wafer support excels itself in particular by a specific surface design and an expedient coating serving as protective layer.

The produced protective layer of the inventive wafer support originates from a conversion either of the wafer support surface or of the components supplied by deposition, for instance by a CVD process or a MOVPE process. BN or PBN is particularly suitable for use as supplied component.

Due to the specific mechanical pre-processing and the configuration of the surface so achieved the produced wafer support is optimised for use in a CVD process in such a way that the electrical and optical characteristics of the layers on the wafers present a high degree of homogeneity.

This means that the desired properties of the protective layer on the wafer support are determined by parameters such as temperature, pressure, time, pre-processing and the type of the mechanical pre-processing in the inventive method.

The inventive wafer support is characterised by a specific coating and a special mechanical processing. It may also be possible that embodiments of the inventive wafer support present only a single specific coating or only special shapes. Both inventive features of the solution to the problem serve to achieve the most homogeneous wafer possible in a CVD process under reproducible conditions.

Further claims reflect expedient embodiments of the production method, with the particular advantages of the inventive wafer support being linked up with these embodiments.

One further claim merely relates to the wafer support as the result of a production method according to one of the method claims.

Moreover, the inventive wafer support is used in a system according to one of the application claims in an approach to solve the problem of the invention.

Moreover an inventive application of the wafer support in a system according to one of the further claims is envisaged for application in a method according to one of the further claims. What is a characteristic of these CVD methods is the application of aggressive gases at high temperatures.

Carbon or graphite, respectively, is expediently suitable as original material of the wafer support so that the production of a clean and thermally resistant wafer support will be ensured which presents good electrical conduction properties in the high-frequency range.

Due to the adaptation of the shape of the wafer support on the basis of the mechanical pre-processing to the type of coating an expedient optimisation of the entire wafer support in correspondence with the problem is possible. It is the object of the wafer support to achieve a high degree of homogeneity of the wafers so produced. Mechanical processing operations are the formation of troughs, bores, and recesses in the wafer in particular.

Due to the novel and inventive manufacturing method, the wafer support produced in accordance with the invention presents optimum characteristics which are an advantage for a high-temperature CVD method operating on aggressive gases:

For instance, the inventive wafer support may have the characteristic of a temperature homogeneity of ΔT<1° C. over a distance of roughly 120 mm on the wafer support. This is the result of a specific inventive shaping such as the provision of troughs on the wafer support in particular. This means that the inventive wafer support is subjected to an appropriate mechanical pre-processing, too, so that wafers as homogeneous as possible can be produced in a CVD process in particular.

A homogeneous electrical conductivity of the used C-block of the wafer support as well as the absorption characteristics of the resulting inventive coating vis-à-vis a thermal radiation are equally important parameters.

An inventive process management permits the establishment of a nucleation or adherence layer in deposition, which furnishes a continuous coating without any fissures at a homogeneous thickness.

For the achievement of a continuous coating it is particularly expedient that the wafer support presents also appropriately rounded edges caused by the mechanical preprocessing operations.

In accordance with the invention further types of mechanical pre-processing may be performed.

These include, for instance, surface smoothing to improve the properties of the converting wafer support surface particularly with respect to the area of attack for the coating components.

It is equally possible to improve the adherence properties, e.g. of PBN on graphite, substantially by homogeneous roughening (e.g. by sand blasting).

It is moreover possible to perform additional pre-processing operations which need not be mechanical operations.

These include in particular the degreasing of the wafer support prior to heating and conversion or coating, respectively. This degreasing operation removes interfering layers from the wafer support.

Another possible additional pre-processing operation, which can be performed particularly prior to wafer support heating, is the impregnation of the graphite contained in the wafer support by means of chemical vapour infiltration. In this operation the density of the graphite is increased by means of a solvent. This increases the conductivity of the wafer support while the high-frequency coupling of the wafer support is improved in its application in a high-temperature CVD process, which means that the thermal efficiency of the wafer support is improved.

The process may be carried out at a low rate so that the production method for the inventive wafer is expediently easy to manage.

The process is carried out within intervals which derive from the time required to form a coherent layer having a sufficient mechanical strength. These intervals are in the range of minutes in particular.

The process temperatures for the production of the inventive wafer support are preferably within the range from 1000° C. to 2200° C. The temperature range is therefore sufficiently and hence expediently above the temperature range in which a CVD process is performed when the inventive wafer support is employed. The process temperature must not be too high in order to avoid a decomposition of the gases. The thermal expansion of the wafer support is equally limited.

Within a pressure range from 10 mbar to 1 bar the characteristics of the inventive wafer support can be expediently optimised. The rate of molecule diffusion into the wafer support depends on the process pressure. At a high pressure the diffusion is slow while at a low pressure the diffusion rate is high.

With an appropriate selection of the coating components it is possible to achieve preferred layers and thus appropriate characteristics of the wafer support protective layer. The coating should be able to resist the aggressive gases used in the CVD process. The undesirable deposition on the wafer carrier is reduced.

The shaping of the wafer support may be expediently matched with the type of coating. Different materials present different coefficients of thermal expansion. The expansions are hence different and thus mechanical strain is created. With a matching to the coating, particularly by appropriate shaping of the wafer support, it is possible to compensate mechanical strain and counteract inhomogeneity linked up therewith.

The inventive wafer support presents resistance to the destruction by reactive and etching gases as well as high temperatures so that the desirable characteristics of the wafer will not be impaired.

Undesirable gases and substances will not penetrate into the wafer support and can hence not be stored therein particularly when the wafer support is employed in a CVD process.

Furthermore, a rapid change of the temperature distribution becomes possible when the temperature of the wafer support is to be changed. This objective is achieved by a coating of the inventive wafer support, which presents a low emissivity in particular.

The wafer support is furthermore characterised by the provision that the entire surface, i.e. also all functional troughs, bores, edges, etc. are resistant vis-a-vis the aggressive atmosphere and the high temperatures.

The coefficient of thermal expansion of the wafer support in its entirety (original material and layer) is almost equal so that mechanical strain will not occur within the wafer support when the temperature is varied or distributed.

The inventive coating is also characterised by the feature that there is no penetration of the reactive gas by diffusion.

Moreover, this coating is chemically inert.

In accordance with the invention the coating is applied on the wafer support in a microscopically smooth form.

Due to the inventive method of producing the coating on the wafer support cracking or microscopic fissures will not occur.

The coating is hence insensitive to temperature variations.

Due to the inventive production method a coherent coating is expediently achieved also on corners and edges and equally on functional troughs and bores as well as on rounded edges.

When the inventive wafer is employed in a CVD process or system the prior art disadvantages outlined above are overcome.

The use of the inventive wafer support in a CVD process entails the expedient advantage that the quality of the wafer to be produced is substantially improved.

Further dependent claims characterise expedient embodiments with respect to applications of the inventive wafer support, particularly in CVD processes.

The invention will be described in the following by exemplary embodiments, without any restriction of the general inventive idea, with reference to the drawing that is referred to expresses verbis with respect to the disclosure of all the particulars which are not described in the text in more detail. In the drawing:

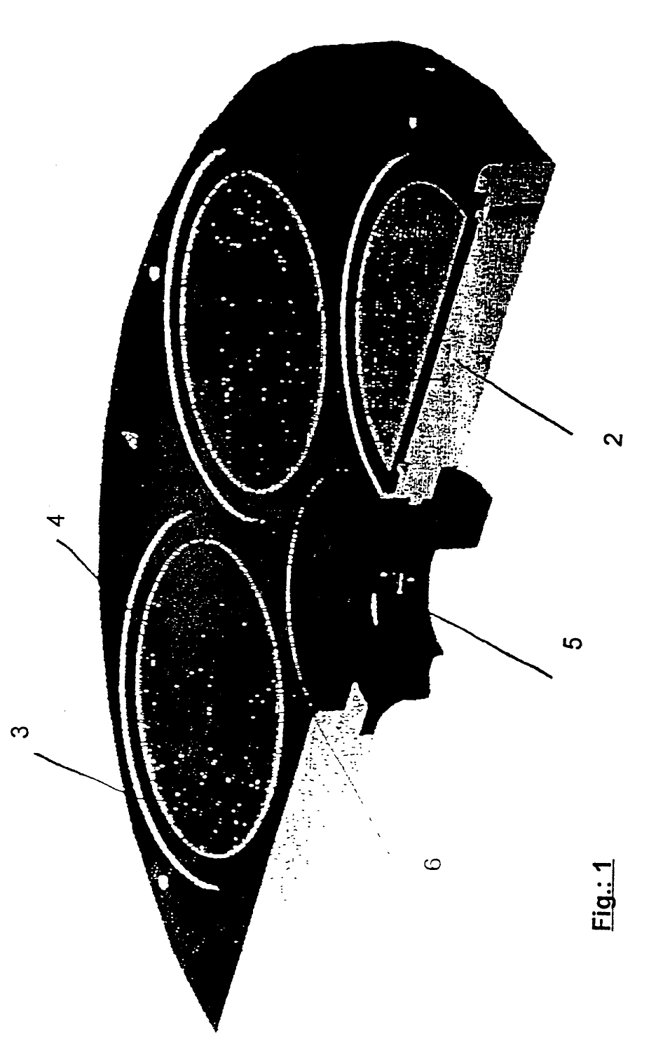

FIG. 1 is an illustration of the inventive wafer support.

In the FIGURE the reference numeral 1 denotes the basic body of the wafer support. The reference numeral 2 identifies functional troughs and recesses for the gas foil rotation. The numeral 3 denotes further functional structures such as areas where the satellites are wider than the wafers. The reference numeral 4 denotes satellites for the wafer. The reference numeral 5 indicates functional bores. The numeral 6 marks appropriately rounded edges.

1. Method of producing a wafer support having a protective layer,
characterised by the following steps:
specific mechanical pre-processing particularly for improving the wafer support consisting of C-graphite or similar material, in view of the homogeneity of wafers to be produced using this support in a CVD process in particular,
cleaning with ethanol for instance,
heating the cleaned wafer support to temperatures particularly within the range from 1000° C. to 2200° C., with the pressure range in the process ranging at 10 mbar to 1 bar in particular,
introducing coating components either
for conversion of the wafer support surface into the protective layer by a reaction of said coating components with the wafer support material, or for
deposition of coating components supplied to said protective layer, with initially a nucleation layer and subsequently the protective layer proper being formed by different gas and process management operations.

2. Method of producing a wafer support,
characterised by the step of:
specific mechanical pre-processing particularly for improving the wafer support consisting of C-graphite or similar material particularly in view of the homogeneity of wafers to be produced with this support in a CVD process.

3. Method of producing a wafer support consisting of C-graphite or a similar material and provided with a protective layer,
characterised by the steps of:
heating the cleaned wafer support to temperatures, particularly in the range from 1000° C. to 2200° C., with the range of pressure in the process ranging at 10 mbar to 1 bar in particular,
introducing coating components either for
converting the wafer support surface into the protective layer by a reaction of the coating components with the wafer support material, or for
deposition of coating components supplied to said protective layer, with initially a nucleation layer and subsequently the protective layer proper being formed by different gas and process management operations.

4. Method according to claim 1 or 2,
characterised in that functional troughs, bores and recesses are formed on said wafer support by said specific mechanical pre-processing, which are completely coated upon termination of the process.

5. Method according to any of the claims 1, 2 or 4,
characterised in that moreover appropriately rounded edges are formed on said wafer carrier by said mechanical pre-processing.

6. Method according to any of the claims 1 to 5,
characterised in that further types of mechanical pre-processing such as surface smoothing or intentional roughening are performed for improving the adherence characteristics.

7. Method according to any of the claims 1 to 6,
characterised in that it is performed with additional pre-processing operations such as degreasing or impregnation, particularly by chemical vapour infiltration.

8. Method according to any of the claims 1, 3 to 7,
characterised by a low rate of process progress.

9. Method according to any of the claims 1, 3 to 8,
characterized in that said low-rate process progress takes place within intervals up to occurrence of a coherent layer having a sufficient mechanical strength, with said intervals being within the range of minutes in particular.

10. Method according to any of the claims 1, 3 to 9,
characterised in that said coating components are formed by Ta, Si, Zr or Nb as well as B and N in particular.

11. Method according to any of the claims 1, 3 to 10,
characterised in that said protective layer is formed by TaC, NbC, ZrC, SiC, SiSiC or appropriately thermally converted carbon or glassy carbon, respectively, or BN or pyrolytic BN, respectively.

12. Method according to any of the claims 1, 3 to 11,
characterised in that the shaping of said wafer support is matched with the type of the coating.

13. Wafer support according to any of the claims 1 to 12.

14. Application of a wafer support according to claim 13 in a Planetary Reactor® or in a satellite system.

15. Application of a wafer support according to claim 13 in a horizontal reactor of the AIX 200 system.

16. Application of a wafer support according to claim 13 in a high-temperature CVD reactor.

17. Application of a wafer support according to any of the claims 14 to 16 in a process based on Gas Foil Rotations operating on aggressive gases.

18. Application of a wafer support according to any of the claims 14 to 17 in a method of producing all binary, ternary, quaternary III-V semiconductors or III-V semiconductors of other complexity such as GaAs, InP, GaN, SiC, GaAsN and similar substances, using aggressive gases.

19. Application of a wafer support according to any of the claims 14 to 18 in a high-temperature CVD method operating on aggressive gases.

20. Application of a wafer support according to any of the claims 14 to 19,
characterised in that said wafer support comprises auxiliary means for process control.

21. Application of a wafer support according to claim 20,
characterised in that said auxiliary means for process control comprise movement sensors to detect the wafer rotation.

22. Application of a wafer support according to claim 20 or 21,
characterised in that said auxiliary means for process control comprise additionally thermometric sensor means.

23. Application of a wafer support according to any of the claims 17 to 22,
characterised in that the heating of said wafer support is performed by resistive heating, high-frequency heating or thermal radiation.

24. Application of a wafer support according to any of the claims 17 to 23,
characterised in that parasitic process deposits on said wafer support are removed by processing at high temperatures.

25. Application of a wafer support according to claim 24,
characterised in that said high temperatures are higher than normal deposition temperatures at roughly 600° C.

26. Application of a wafer support according to any of the claims 17 to 25,
characterised in that moreover parasitic process deposits on said wafer support are removed by etching processes.

27. Application of a wafer support according to claim 26,
characterised in that particularly HCl or ammoniac are used as aggressive gases.

28. Application of a wafer support according to any of the claims 17 to 27,
characterised in that it is a MOVPE process.
